(19) United States
(12) Patent Application Publication
(10) Pub. No.: US 2010/0182016 A1
(43) Pub. Date: Jul. 22, 2010

(54) ELECTRONIC STATUS DETECTION DEVICE

(75) Inventors: Sven Hild, Hagen (DE); Martin Schneider, Wiedemar (DE); Stefan Riefers, Krefeld (DE); Daniel Jendritza, Krefeld (DE)

Correspondence Address: BAINWOOD HUANG & ASSOCIATES LLC, 2 CONNECTOR ROAD, WESTBOROUGH, MA, 01581, US

(73) Assignee: HUF ELECTRONICS GMBH, Velbert (DE)

(21) Appl. No.: 12/647,095

(22) Filed: Dec. 24, 2009

Related U.S. Application Data
(63) Continuation of application No. PCT/EP2008/058121, filed on Jun. 26, 2008.

(30) Foreign Application Priority Data
Jun. 26, 2007 (DE) 20 2007 009 033.1

(51) Int. Cl. G01R 27/32; B60L 1/00

(52) U.S. Cl. 324/635; 307/9.1

(57) ABSTRACT

An electronic status detection device for wireless detection of at least one status of an apparatus, wherein the status detection device comprises at least two resonant circuits, of which at least one resonant circuit is active and one resonant circuit is passive, wherein the active resonant circuit comprises at least one control device. A status detection device such as this makes it possible, for example, to reliably detect the presence or the absence of belt clips in safety belt locks.

### BACKGROUND OF THE INVENTION

The present invention relates to an electronic state detection device for vehicles for wirelessly detecting at least one state of an apparatus. Furthermore, the present invention also relates to a motor vehicle having at least one state detection device. The invention is used for monitoring states of at least one appliance or one apparatus in vehicles and is used particularly in the automotive sector.

In modern vehicles, it is increasingly necessary to monitor states and functions, and components, appliances, units or apparatuses contained therein. This can be derived partly from legal regulations, and also from the aim of improving safety for vehicle occupants or increasing comfort, for example. Thus, in modern vehicles, the proper closing of doors, the fastening of safety belts and/or the depression of the brake pedal when starting automatic vehicles is monitored, for example. In addition, seat occupancy identification can also be covered by the vehicle, for example.

In this case, attempts are increasingly being made to take account of the known and detected vehicle states when controlling the overall vehicle system. This can be taken into account in different airbag release times, blockage of the engine control and/or the output of warnings to the driver, for example. By way of example, a wireless switch detection system is known from DE 199 19 158 A1 for this purpose. This wireless switch detection system comprises a central transmitter for sending or transmitting a transmitter signal. The system likewise comprises a remote switch which is at a distance from the central transmitter and can adopt at least two states. An indicator circuit responds to the transmitter signal and is supplied with power thereby. The indicator circuit detects the state of the remote switch and, in response to the transmitter signal, delivers an indicator signal which indicates the state of the switch. A central receiver receives the indicator signal. Whereas such an apparatus allows intended state detection to be performed for apparatuses in vehicles, the wireless switch detection system described requires the arrangement of a relatively complex indicator circuit. In this case, the active indicator circuit needs to be supplied with power in order to be able to send appropriate signals. This makes it relatively complicated and expensive.

### SUMMARY OF THE INVENTION

It is therefore an object of the present invention to solve at least some of the problems outlined with reference to the prior art and, in particular, to specify an apparatus which allows state detection in simplified and less expensive fashion.

These objects are achieved by means of an apparatus based on the features of claim 1, and by means of a motor vehicle having the features of claim 9. Further advantageous refinements of the invention are specified in the dependent claims. It should be pointed out that the individually presented features in the dependent claims can be combined with one another in any technologically meaningful manner and define further refinements of the invention. Furthermore, the features specified in the claims are specified and explained more precisely in the description, with further preferred exemplary embodiments of the invention being illustrated.

Accordingly, an electronic state detection device for vehicles for wirelessly detecting at least one state of an apparatus is proposed, wherein the state detection device is arranged particularly in a vehicle interior and comprises at least two resonant circuits, of which at least one resonant circuit is of active design and one resonant circuit is of passive design, wherein the active resonant circuit comprises at least one control device.

A fundamental idea of the present invention is to use an active and a passive resonant circuit for the state detection identification. This allows the passive resonant circuit to be of particularly simple, compact and inexpensive design. In this case, the passive resonant circuit is preferably arranged at the location at which a state can be detected. The active resonant circuit, for its part, is connected to a control device which, although it may be arranged in direct proximity to the passive resonant circuit, is usually accommodated at a distance therefrom at another location in the vehicle. In line with the present invention, this merely requires only parts of the respective resonant circuits not to exceed a maximum distance. A fundamental function of the state detection device according to the invention is that the control device feeds power into (only) one resonant circuit, as a result of which said circuit is operated actively.

In addition, a second passive resonant circuit, which does not have a direct connection to a power source, is provided. Both resonant circuits, that is to say the active resonant circuit and the passive resonant circuit, are coupled to one another by means of a magnetic field, so that the actively operated resonant circuit can excite the passive resonant circuit by means of the magnetic coupling. The passive resonant circuit is also distinguished particularly in that it assumes precisely one associated oscillatory characteristic for each state that can be detected. When the passive resonant circuit has been excited by the active resonant circuit, the oscillatory characteristic of the passive resonant circuit is then monitored. This is done by the control device, for example, which can detect and evaluate what is known as a resonance of the passive resonant circuit. In this case, the passive resonant circuit is in a form such that it can adopt different oscillatory characteristics according to the number of states which are to be monitored. If, in a particularly simple embodiment, for example, only two states need to be monitored, it is sufficient to select a passive resonant circuit which can only adopt two oscillation states. By way of example, such states can describe the presence or absence of belt clips in safety belt buckles. If a safety belt buckle is connected, it can adopt a first state, whereas if the safety belt is open, a second state is represented.

For the purpose of detecting the state, the control device can now check the state of the belt buckle continually or upon certain events. By way of example, continually can be understood to mean at constant intervals of time. A check can thus be made regularly at intervals of (approximately) ten seconds, for example. Alternatively, it is also possible for an appropriate state to be checked only upon certain events, such as when the driver's door is opened or the engine is started, however. On account of the passive resonant circuit's being excited by the active resonant circuit, said circuit reacts with an oscillatory characteristic produced in line with the respective state. This oscillatory characteristic is detected and evaluated by the control device. Thereafter, the state detected in this manner is used further for operation of the overall vehicle. By way of example, this may involve advice to the driver advising him that the belt buckle is not closed. Alternatively, a vehicle control device can also prevent functions such as starting the engine, however, so as to prevent driving without the belt device closed.

It is particularly advantageous in this context if the passive resonant circuit has only passive electronic components. Such passive electronic components are coils or capacitors, for example. These components can be combined to form two groups. One group is formed by capacitive components whereas another group is formed by inductive components. In addition to the capacitive and inductive components, it is then also necessary to provide supply line means for electronically connecting the components and circuit devices. All of these are passive components which are used in the passive resonant circuit. The switching devices are used for detecting the different states. They allow a particularly simple and distinctive, explicit way of altering the oscillatory characteristic of the passive resonant circuits on the basis of states of the apparatus which is to be monitored. If such a switch is arranged in a resonant circuit comprising a capacitor and a coil, for example, then it may be open in a first state, for example, when the resonant circuit is capable of oscillation. In a second state, the switch may then be closed and bypass both the capacitive component and the inductive component, as a result of which the resonant circuit is incapable of oscillation. This is a particularly simple, inexpensive and reliable embodiment of the invention. Alternatively, it is also possible for other passive components to be used, however, which can alter their physical properties on the basis of states which are to be monitored. In particular, electrical resistor components, capacitive components or inductive components which change their properties on the basis of states of the device which is to be monitored are suitable for this.

In addition, the at least two resonant circuits should be coupled by a magnetic field. This primarily comes down to the arrangement of the passive resonant circuit in a magnetic near field of the active resonant circuit. In particular, this means that the passive resonant circuit is arranged in the near field and at a distance of no more than 20 millimeters, for example. In contrast to transmission of radio signals which can be transmitted over very long distances, coupling by a (purely) magnetic field is a question of a relatively short physical spacing. To this end, the present invention provides for the two resonant circuits to be arranged very close to one another physically, as a result of which the passive resonant circuit is situated in the magnetic field produced by the active resonant circuit.

Quite particularly suitable for this purpose is the coupling which corresponds to a transformer coupling. Transformer couplings are used in AC transformers, for example. These involve reinforcement of the coupling for the use of iron cores on which two coils are arranged, for example. Each of these coils in this case corresponds to an inductive component of a resonant circuit. Within the context of the present invention, it is then desirable if both inductive components could share a common iron core or magnet core. This is not the case in many instances of application, however, which is why the passive resonant circuit or the inductive component thereof is then arranged in proximity to the inductive component of the active resonant circuit. The resonant circuits which are thus situated physically close to one another ensure that the control device for the active resonant circuit can excite the passive resonant circuit and detect and evaluate the oscillatory characteristic thereof even in interference fields.

It has been found to be particularly beneficial if the respective resonant circuits are at a maximum distance of no more than 15 cm (centimeters) from one another. Particularly when the maximum distance is at most 5 cm, particularly reliable detection operations have been able to be presented. Within the context of the invention, the various components of the resonant circuits can also be arranged at an appropriate distance from one another. This has the advantage that the resonant circuits are well matched to the respective installation dimensions in terms of design and arrangement within the vehicle. It is thus possible, by way of example, for the capacitor and the switch in the passive resonant circuit to be arranged in a belt buckle housing, while the coil, which forms the inductive component, can be arranged at a lower end of a buckle stalk and is connected to the other components merely by means of cable connection. The coil arranged at the lower end of the buckle stalk may thus be arranged particularly close to a further coil in the active resonant circuit, which coil is permanently arranged directly next to the buckle stalk on the body work, for example.

It is therefore particularly advantageous if the resonant circuits have inductive components which comply with the maximum distance.

In line with one particularly preferred development of the invention, provision is made for at least one passive resonant circuit to contain a plurality of switches for bypassing at least one capacitive and/or inductive component. The arrangement of a plurality of switches allows a plurality of states to be monitored. By way of example, one embodiment may thus have provision for a plurality of capacitors and switches to be arranged relative to one another such that each switch can bypass a capacitor associated therewith. If the respective (binary) switch is closed, the associated capacitor is bypassed. If the switch is open, the associated capacitor in the resonant circuit acts in line with its capacitance. The passive resonant circuit can therefore adopt a plurality of oscillation states which respectively correspond to a quite particular state of the associated switches. Particularly when different capacitor capacitances are used, the eight circuit states adopted by three switches, for example, can be distinguished from one another with particular clarity.

In this case, examples of further functions may be the identification of seat occupancy, use of children's seat fastening devices or else other states, such as open or closed states of vehicle closure systems, to name but a few by way of example.

As already mentioned previously, it is quite particularly advantageous within the context of the invention if at least part of a passive resonant circuit is arranged in a belt buckle. In the case of this application, the present invention can be used to produce a particularly simple, reliable and durable device which is used for detecting the use state of the belt buckle.

Furthermore, the object according to the invention is solved by providing for a motor vehicle to be equipped with at least one state detector, the latter being designed in line with the invention and being connected for control purposes to at least one control device of the motor vehicle. It therefore becomes possible to take account of the information supplied from the state detection device with regard to the respective vehicle state when controlling the overall vehicle. The information can thus be used further in a control device of the motor vehicle and can thus be used to increase travel comfort and vehicle safety.

### BRIEF DESCRIPTION OF THE DRAWINGS

The invention and the technical surroundings are explained in more detail below with reference to the figures. It should be pointed out that the figures show particularly preferred variant embodiments of the invention which do not limit the invention. The figures are schematic illustrations in which:

FIG. 1 shows an illustration of a belt buckle according to the invention,

FIG. 2 shows a circuit diagram of a state detection device according to the invention,

FIG. 3 shows a signal profile for the state detection device shown in FIG. 2,

FIG. 4 shows a circuit diagram of a further embodiment of a state detection device,

FIG. 5 shows a signal profile for the state detection device shown in FIG. 4,

FIG. 6 shows a magnetic field diagram in a first embodiment,

FIG. 7 shows a magnetic field diagram in a second embodiment,

FIG. 8 shows a magnetic field diagram in a third embodiment; and

FIG. 9 shows a magnetic field diagram in a fourth embodiment.

### DETAILED DESCRIPTION

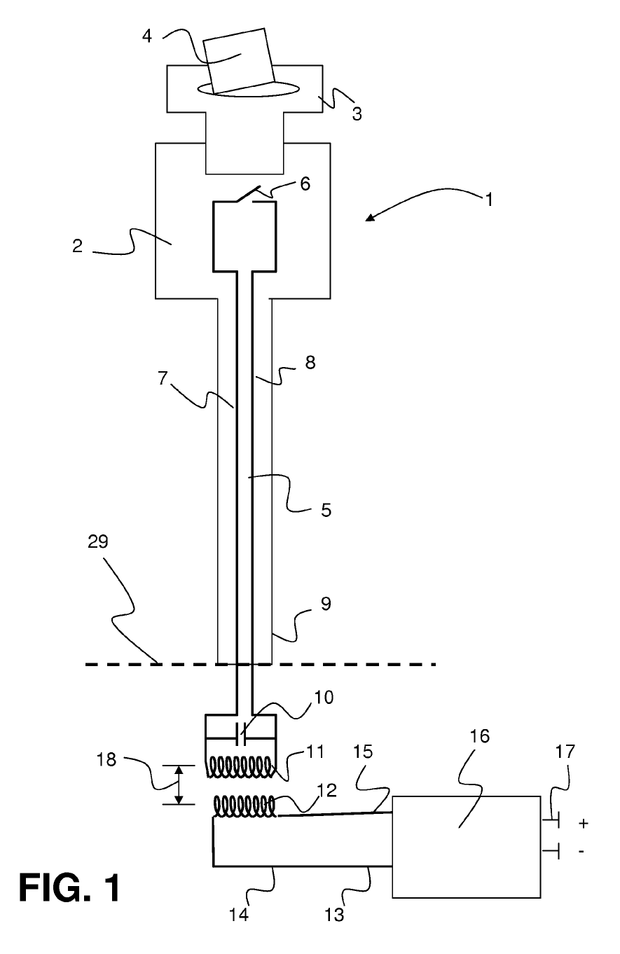

FIG. 1 shows a belt buckle 1 designed in accordance with the invention in a schematic side view. The belt buckle 1 has a housing 2 which accommodates the mechanical part—which is not shown here—of the belt buckle. The belt buckle 1 has a belt clip 3 inserted into it on which a belt strap 4 is turned around. The housing 2 also partially accommodates a passive resonant circuit 5. In the embodiment shown, the housing 2 contains a switch 6 and a portion of a first electrical line 7 and of a second electrical line 8 within the housing 2. A buckle stalk 9 projects downward out of the housing 2. The buckle stalk 9 is then mounted on the vehicle 29, further comments concerning the mechanical mounting of the buckle stalk 9 being dispensed with at this juncture. In parallel with the buckle stalk 9, the first line 7 and the second line 8 are routed downward, to where the further components of the passive resonant circuit 5 are located. In this case, the passive resonant circuit 5 has a capacitor 10 and a coil 11 which are arranged in parallel with one another and which can be bypassed by the switch 6. Underneath, there is a further coil 12 of the active resonant circuit 13. In this case, the coil 12 is connected to a control device 16 by means of a third electrical line 14 and a fourth electrical line 15.

The control device 16 is supplied with power by a power supply 17. This power supply 17 may be the 12-volt or 24-volt system in vehicles, for example. The control device 16 then prompts state identification by exciting the coil 12, which is arranged within a maximum distance 18 relative to the coil 11. Since the coil 11 is situated within the magnetic field of the coil 12, the passive resonant circuit undergoes excitation by virtue of this coupling and oscillates in accordance with the set state. When the switch 6 is open, a different oscillatory characteristic is obtained in this case than when the switch 6 is closed.

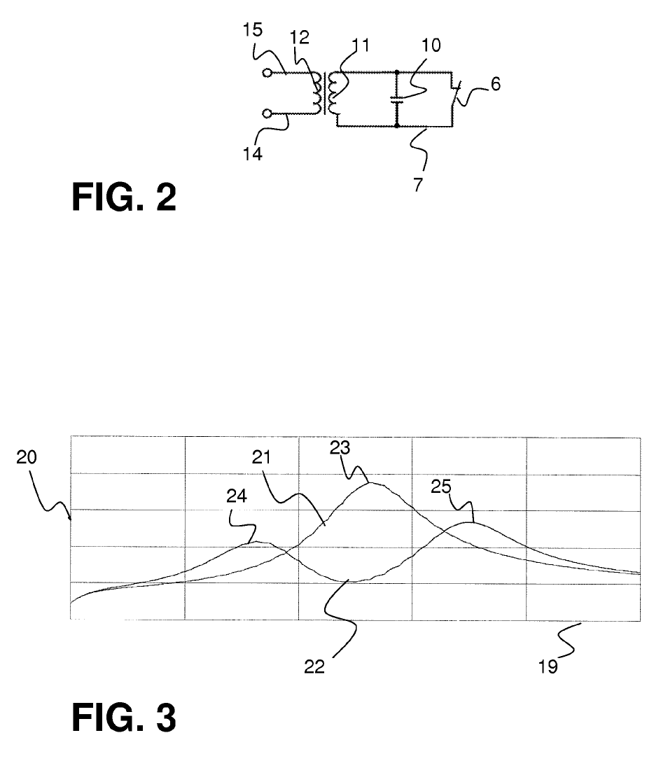

FIG. 2 shows the arrangement of the resonant circuits shown in FIG. 1 again in schematic form. On the left-hand side, the coil 12 is connected to the control device—not shown here—by means of the third electrical line 14 and the fourth electrical line 15. On the right-hand side in FIG. 2, the coil 11 is connected to the capacitor 10 and to the switch 6 by means of the first electrical line 7 and the second electrical line 8.

FIG. 3 shows the possible state-dependent oscillatory characteristic of the resonant circuit shown in FIG. 2. The frequency 19 is plotted in the horizontal direction in this graph, and the associated voltage 20 is plotted in the vertical direction. It should be noted that instead of the associated voltage 20 it is also possible for the associated current level to be plotted in the vertical direction, but this does not cause the graph to differ much.

In this case, the first curve 21 and second curve 22 shown respectively correspond to a circuit state of the switch 6. If the switch 6 is open, the voltage/frequency profile corresponds to the second curve 22. If the switch 6 is closed, the voltage/frequency profile corresponds to the first curve 21. In this case, it can easily be seen that in the closed state a singular maximum 23 occurs, with the open state of the switch 6 giving rise to two maxima, a first maximum 24 and a second maximum 25. This curve profile can be detected and evaluated by means of the control device, in which case the occurrence of two maxima 24, 25 can be distinguished with certainty, in contrast to a single maximum 23, which means that the different states of the switch 6 can subsequently be detected with certainty. Overall, it is therefore possible to use a passive resonant circuit 5 together with an active resonant circuit 13 to detect the state of the switch 6 in a particularly simple manner.

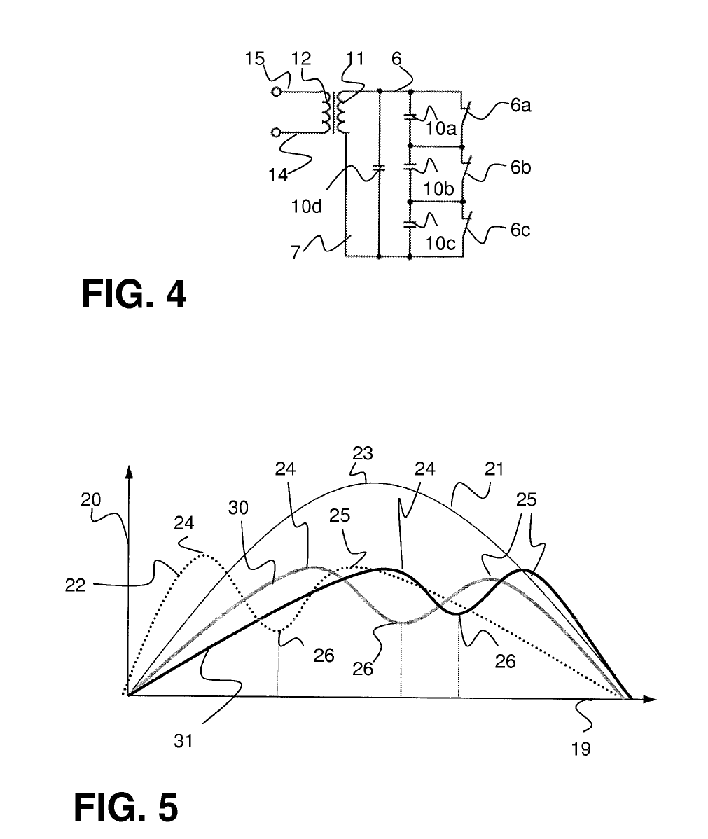

FIG. 4 now schematically shows a circuit which, in this case, has four capacitors 10 (10a, 10b, 10c, 10d) and three switches 6 (6a, 6b, 6c). On the left-hand side, there is again the active coil 12 with the third electrical line 14 and the fourth electrical line 15. This is again the active resonant circuit 13. On the right-hand side, there is the passive resonant circuit 5 with the passive coil 11 and the first electrical line 8 the second electrical line 8. In addition, the passive resonant circuit 5 has the capacitors 10 (10a, 10b, 10c, 10d) in this arrangement, each of the capacitors 10a, 10b and 10c having a respective associated switch 6a, 6b and 6c which can bypass this capacitor.

FIG. 5, like FIG. 3, shows a voltage/frequency profile. The frequency 19 is again plotted in a horizontal direction and the voltage 20 in the vertical direction. The first curve 21 has a singular maximum 23 and in this case again corresponds to the state in which all switches are closed. In the fully closed state, the first curve 21 accordingly has only one maximum. A dotted line is used to show a second curve 22 which likewise, as already described above in connection with FIG. 3, has two maxima 24, 25. In this case, the second curve 22 corresponds to the circuit state in which the switch 6a is open. As a consequence of the switch 6a being opened, the second curve 22 additionally has a first minimum 26. In this case, the first minimum 26 always corresponds to the open state of the switch 6a.

The third curve 30 shown likewise has two maxima 24, 25, and also a first minimum 26 (minimum shows closed switch 6b). In addition, a fourth curve 31 is also shown which likewise has two maxima 24, 25 and also a first minimum 26 (minimum shows closed switch 6c). It is therefore possible for the three switches to be monitored in a simple manner. If there is no minimum and only one maximum, all the switches are closed. The timing of the minima (that is to say the position thereof on the horizontal axis) in the course of a checking cycle can serve as a reference for which switch is now closed and which switch is open. In this context, it should be noted that for the sake of clarity only those states in which individual switches were opened have been discussed. Within the context of the invention, however, it is also no problem to identify different circuit states in which two or all switches 6a to 6c are open.

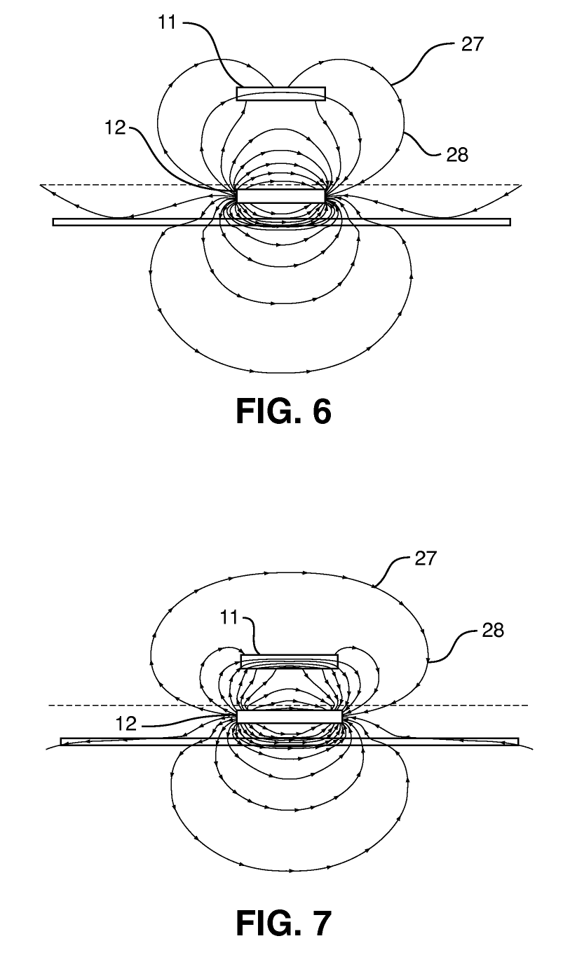

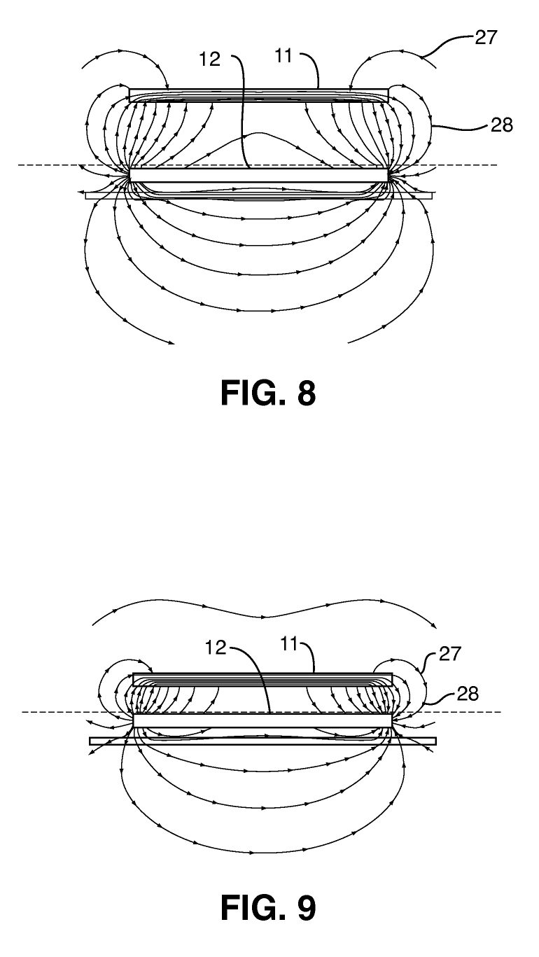

FIG. 6 schematically shows field lines 27 in a magnetic field 28 formed between the passive coil 11 and the active coil 12. In this case the passive coil 11 and the active coil 12 are at a relatively long distance from one another and are in relatively short form. FIG. 7 shows a magnetic field 28 in which the passive coil 11 and the active coil 12 are arranged relatively close to one another. FIG. 8 shows a magnetic field 28 with its field lines 27, in which the passive coil 11 and the active coil 12 are in elongate form and are spaced relatively far apart, and FIG. 9 shows the situation in which the passive coil 11 and the active coil 12 are likewise in elongate form, but in this case are at a relatively short distance from one another, as a result of which the magnetic field 28 behaves in accordance with the field lines 27. In all the figures, it can be seen that the invention can be applied with the desired success within the prescribed maximum distances. The coupling for the passive coil 11 and the active coil 12 by means of the magnetic field 28 works in the desired manner in this case. The different magnetic fields indicated here are formed particularly on the basis of the length of the core of the transformer which means that this length of the core of the transformer particularly influences the near field or the range or the maximum distance of the two resonant circuits.

For the rest, it should be pointed out that the exemplary embodiments shown do not limit the present invention in any way. On the contrary, numerous modifications of the invention are possible within the scope of the patent claims. Thus, by way of example, it is possible for numerous other embodiments instead of the illustrated switch combinations and state combinations and also forms, particularly of the passive resonant circuits 5, to be applied within the scope of the invention.

### LIST OF REFERENCE SYMBOLS

1 Belt buckle
2 Housing
3 Belt clip
4 Belt strap
5 Passive resonant circuit
6 Switch
7 First electrical line
8 Second electrical line
9 Buckle stalk
10 Capacitor
11 Passive coil
12 Active coil
13 Active resonant circuit
14 Third electrical line
15 Fourth electrical line
16 Control device
17 Power supply
18 Maximum distance
19 Frequency
20 Voltage
21 First curve
22 Second curve
23 Singular maximum
24 First maximum
25 Second maximum
26 First minimum
27 Field lines
28 Magnetic field
29 Vehicle
30 Third curve
31 Fourth curve

What is claimed is:

1. An electronic state detection device for wirelessly detecting at least one state of an apparatus, wherein the state detection device comprises at least two resonant circuits, of which at least one resonant circuit is of active design and one resonant circuit is of passive design, wherein the active resonant circuit comprises at least one control device.

2. The state detection device as claimed in claim 1, wherein the passive resonant circuit has only passive electronic components.

3. The state detection device as claimed in claim 1, wherein the at least two resonant circuits are coupled by a magnetic field.

4. The state detection device as claimed in claim 3, wherein the coupling corresponds to a transformer coupling.

5. The state detection device as claimed in claim 1, wherein the respective resonant circuits are at a maximum distance of no more than 15 cm from one another.

6. The state detection device as claimed in claim 5, wherein the respective resonant circuits have inductive components which comply with the maximum distance.

7. The state detection device as claimed in claim 1, wherein at least one passive resonant circuit contains a plurality of switches for bypassing at least one capacitive and/or inductive component.

8. The state detection device as claimed claim 1, wherein at least part of a passive resonant circuit is arranged in a belt buckle.

9. A motor vehicle having at least one state detection device as in claim 1 being connected for control purposes to at least one control device of the motor vehicle.

10. The motor vehicle as claimed in claim 9, wherein the passive resonant circuit of the state detection device has only passive electronic components.

11. The motor vehicle as claimed in claim 9, wherein the at least two resonant circuits of the state detection device are coupled by a magnetic field.

12. The motor vehicle as claimed in claim 11, wherein the coupling corresponds to a transformer coupling.

13. The motor vehicle as claimed in claim 9, wherein the respective resonant circuits of the state detection device are at a maximum distance of no more than 15 cm from one another.

14. The motor vehicle as claimed in claim 13, wherein the respective resonant circuits have inductive components which comply with the maximum distance.

15. The motor vehicle as claimed in claim 9, wherein at least one passive resonant circuit of the state detection device contains a plurality of switches for bypassing at least one capacitive and/or inductive component.

16. The motor vehicle as claimed claim 9, further comprising a safety belt buckle and wherein at least part of a passive resonant circuit of the state detection device is arranged in the safety belt buckle.
